(19) United States
(12) Patent Application Publication
(10) Pub. No.: US 2017/0012182 A1
(43) Pub. Date: Jan. 12, 2017

(54) White Light LED Filament Having Blue Light Emitting Units and a Strip-Shaped Fluorescent Wafer

(71) Applicants: Dun-Hua Cao, Kunshan Suzhou (CN); Yue-Shan Liang, Kunshan Suzhou (CN); Kejun Ma, Kunshan Suzhou (CN)

(72) Inventors: Dun-Hua Cao, Kunshan Suzhou (CN); Yue-Shan Liang, Kunshan Suzhou (CN); Kejun Ma, Kunshan Suzhou (CN)

(21) Appl. No.: 14/795,828

(22) Filed: Jul. 9, 2015

(51) Int. Cl. H01L 33/50; H01L 33/64; H01L 25/075

(52) U.S. Cl. CPC H01L 33/505; H01L 25/0753; H01L 33/502; H01L 33/501; H01L 33/642; H01L 33/641

(57) ABSTRACT

The present invention relates to a white light LED lamp and a filament. The white light LED filament comprises light emitting units and a strip-shaped fluorescent wafer(s) at least positioned at one side of the light emitting units, wherein the light emitting units are blue-emitting chips connected by a metal wire or an electric conductive circuit, and wherein electrodes are arranged at the end(s) of the fluorescent wafer. Without any lens, the filament of the present invention has a simple structure. A white light LED lamp using the filament realizes a 360° stereo-luminescence, and shows the advantages of low cost, excellent heat radiation, high luminous efficacy and so on.

### TECHNICAL FIELD OF THE INVENTION

The present invention relates to LED luminous technique field, and in particular, relates to a white light LED lamp and a filament.

### TECHNICAL BACKGROUND

LED is a solid semiconductor device which can directly convert electric energy into light energy. As compared to conventional incandescent lamp and fluorescent lamp, white light LED shows the advantages of low power consumption, high luminescence efficiency, long service life, energy saving and environmental protection, and so on. Consequently, it is not only widely used for daily illumination, but also enters the display device field. Currently, white light LEDs mainly use the combination of blue-emitting chips and yellow-emitting fluorescent powder Ce:YAG which can be effectively excitated by blue light, whereby the complementary yellow light and the blue light are mixed to produce white light based on the lens principle.

Conventional fluorescent powder-packaging LED has the following disadvantages: low fluorescent powder excitation efficiency, low light conversion efficiency, poor homogeneity, high luminous decay, and poor chemical and physical properties; in addition, conventional LED lamps have a complex structure with high cost. Chinese patent CN103322525A discloses a LED lamp and a filament thereof, wherein the LED filament comprises a substrate, a light emitting unit secured onto at least one side of the substrate, and a sealing adhesive layer surrounding the periphery of the light emitting unit, and the light emitting unit comprises a plurality of blue-emitting chips and red-emitting chips regularly distributed on the substrate and sequentially connected to one another in series. The LED filament has good color rendering property, but has poor thermal conductivity and luminous efficacy due to the presence of the sealing adhesive layer at the periphery of the filament as the sealing adhesive layer is made of fluorescent power-containing transparent colloid material.

### CONTENTS OF THE INVENTION

The technical problem to be solved by the present invention is to overcome the drawbacks in the prior art and to provide an LED filament having simpler structure, higher thermal conductivity, higher fluorescent efficacy and better color rendering property, which can be used to realize 360° stereo-luminescence.

To solve the above technical problem, the present invention provides a white light LED filament comprising light emitting units and a strip-shaped fluorescent wafer(s) at least positioned on one side of the light emitting units, wherein the light emitting units are blue-emitting chips connected by a metal wire or an electric conductive circuit, and wherein electrodes are arranged at the end(s) of the fluorescent wafer.

Furthermore, the composition of the strip-shaped fluorescent wafer is Ce:YAG with a chemical formula: (Y₁₋ₓ₋ₘAₓCeₘ)₃(Al_{1-y}B_{y})₅O₁₂, wherein 0≦x≦1, 0≦y≦1, 0≦m≦0.01, A is Lu, Tb, Pr, La or Gd, and B is Ga, Ti, Mn, Cr or Zr.

Furthermore, the strip-shaped fluorescent wafer has a length of 5 mm˜50 mm, a width of 1 mm˜4 mm, and a thickness of 0.2 mm˜1 mm

Furthermore, the electrodes are arranged at the same end or both ends of the filament.

Furthermore, the light emitting units are fixed on the strip-shaped fluorescent wafer(s) by silica gel, epoxy resin or a supporting frame.

Furthermore, the silica gel or the epoxy resin is doped with red fluorescent powder.

Furthermore, the light emitting units are alternately arranged blue-emitting chips and red-emitting chips.

Furthermore, a strip-shaped glass sheet having the same size of the strip-shaped fluorescent wafer is affixed to the other side of the light emitting units.

Furthermore, a blue light reflecting layer is affixed to the other side of the light emitting units, wherein the size of the blue light reflecting layer matches the blue-emitting chips.

Furthermore, a sheet-shaped fluorescent wafer is affixed to the other side of the light emitting units, and wherein the size of the sheet-shaped fluorescent wafer matches the blue-emitting chips.

Meanwhile, the present invention also provides an LED lamp comprising any of the above mentioned LED filaments.

As compared to prior art, the white light LED filament prepared by the method of the present invention with fluorescent wafer shows the following beneficial effects:

1) low cost: without complex lens structures, the device has a simple structure;

2) excellent thermal conductivity: a fluorescent wafer having higher thermal conductivity as compared to fluorescent powders simply doped in colloid is more effective in heat transfer;

3) high luminous efficacy: by avoiding the optical loss caused by lens, the white light LED device has a luminous efficacy which is 5˜10% higher than that of devices using common wafers; as for a filament structure of double-faced luminescence, the increase of the luminous efficacy is more remarkable; and

4) realizing a 360° stereo-luminescence.

### BRIEF DESCRIPTION OF THE DRAWINGS

To clearly describe the technical solutions in the examples of the invention, the figures used in the examples are described in brief. Obviously, the following figures are only used for illustrating some examples of the present invention, and a person skilled in the art can obtain other figures based on the attached figures without paying inventive efforts.

FIG. 1 is a schematic diagram for illustrating the structure in Example 1 of the present invention.

FIG. 2 is a schematic diagram for illustrating the structure in Example 4 of the present invention.

FIG. 3 is a schematic diagram for illustrating the structure in Example 5 of the present invention.

FIG. 4 is a schematic diagram for illustrating the structure in Example 6 of the present invention.

In the figures, “1”: strip-shaped fluorescent wafer; “2”: blue-emitting chip; “3”: metal wire or electric conductive circuit; “4”: electrode; “5”: silica gel, or epoxy resin; “6”: blue light reflecting layer; “7”: red light supplementing layer; “8”: sheet-shaped fluorescent wafer; and, “9”: red-emitting chips.

### DETAILED DESCRIPTION OF THE EMBODIMENTS

The present invention will be further illustrated by embodiments referencing the accompanying drawings. According to the following description and the attached claims, the advantages and characters of the present invention are clear. It is to be noted that the figures are in simplified forms and are not in precise scales, which are used only for the purpose of illustrating the examples of the invention in a convenient and clear way.

### Example 1

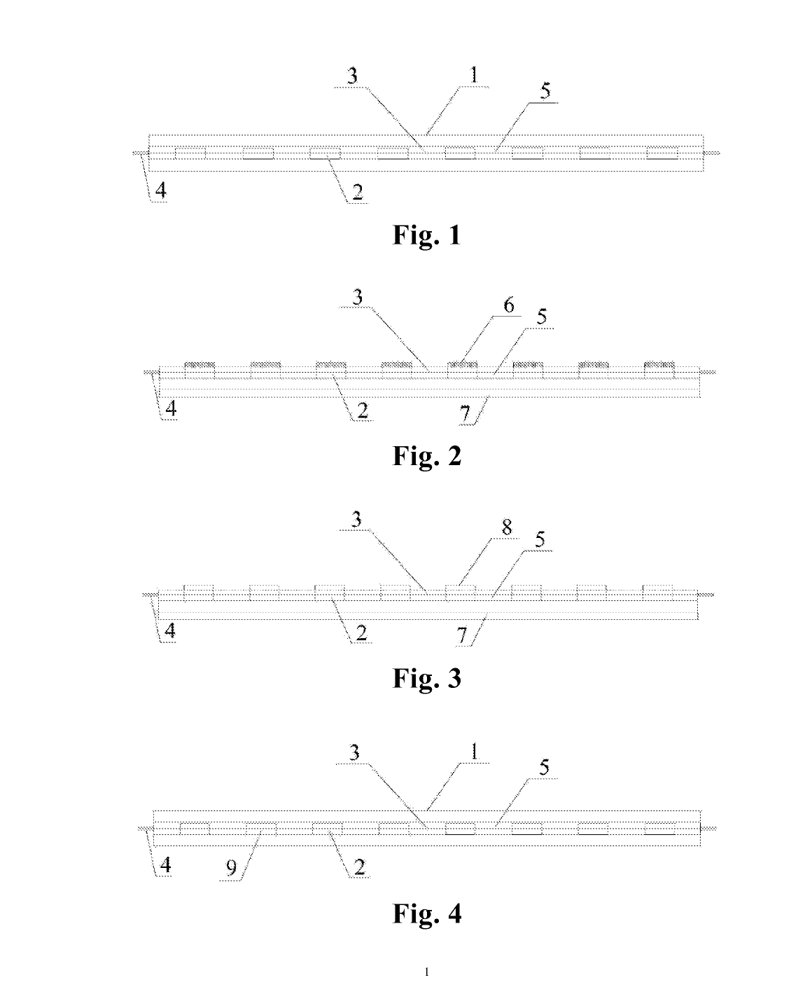

FIG. 1 is a schematic diagram showing the structure in Example 1 of the present invention, i.e., a white light LED filament comprising light emitting units and strip-shaped fluorescent wafers 1 positioned on both sides of the light emitting units, wherein the light emitting units are blue-emitting chips 2 connected in series by a metal wire or an electric conductive circuit 3, the blue-emitting chips 2 are fixed on the strip-shaped fluorescent wafers 1 by a silica gel 5 dot array, and electrodes 4 connected by the metal wire 3 are arranged at both ends of the strip-shaped fluorescent wafer 1.

The strip-shaped fluorescent wafer 1 has a length of 5 mm˜50 mm, a width of 1 mm˜4 mm, and a thickness of 0.2 mm˜1 mm. The strip-shaped fluorescent wafer 1 is used as the substrate of the light emitting units, and is a light transmitting layer. Light emitted by the light emitting units can pass through the strip-shaped fluorescent wafer 1 and emerge from the other side of the wafer. The application of the strip-shaped fluorescent wafers 1 can reduce the light loss by avoiding the use of lens, increase the light-emitting angle and light output efficiency, such that a 360° luminescence at all angles is realized. Moreover, as compared to ceramic and epoxy resin, the strip-shaped fluorescent wafer 1 has better thermal conductivity and thus can effectively transfer heat from the chips. Meanwhile, the properties of the strip-shaped fluorescent wafer 1, such as high temperature and high pressure endurance and anti-oxidization, also contribute to the improvement of the filament quality.

### Example 2

Example 2 is the same as Example 1 except that in the second embodiment of the present invention, the blue-emitting chips are fixed on the fluorescent wafer via a supporting frame, and the electrodes are arranged at the same end of the fluorescent wafer.

### Example 3

Example 3 is the same as Example 1 except that in the third embodiment of the present invention, a strip-shaped glass sheet having the same size of the strip-shaped fluorescent wafer is affixed to the other side of the light emitting units, and the silica gel is doped with red fluorescent powder to adjust the color rending property.

### Example 4

Example 4 is the same as Example 1 except that in the fourth embodiment of the present invention, as shown in FIG. 2, a blue light reflecting layer 6 is affixed to the other side of the light emitting units, and the size of the blue light reflecting layer 6 matches the blue-emitting chips 2; and, a red light supplementing layer 7 is arranged on the strip-shaped fluorescent wafer 1.

### Example 5

Example 5 is the same as Example 1 except that in the fifth embodiment of the present invention, as shown in FIG. 3, a sheet-shaped fluorescent wafer 8 is affixed to the other side of the light emitting units, and the size of the sheet-shaped fluorescent wafer 8 matches the blue-emitting chips 2; and, a red light supplementing layer 7 is arranged on the strip-shaped fluorescent wafer 1.

### Example 6

Example 6 is the same as Example 1 except that in the sixth embodiment of the present invention, as shown in FIG. 4, the light emitting units are alternately arranged blue-emitting chips 2 and red-emitting chips 9 which are connected by an electric conductive circuit 3. The blue-emitting chips 2 and red-emitting chips 9 are fixed on the strip-shaped fluorescent wafers 1 by an epoxy resin 5 dot array. Electrodes 4 connected to the electric conductive circuit 3 are arranged on both ends of the fluorescent wafer. The gel used in this example is not doped with red fluorescent powder, and the color rendering property is adjusted by the red-emitting chips.

Based on the above disclosures, the present invention further provides an LED lamp comprising the above mentioned LED filament and a glass shell housing the filament. The arrangement of the LED filament allows the LED lamp to realize a 360° stereo-luminescence.

The present invention produces the following beneficial effects: low cost: without complex lens structures, the device has a simple structure; excellent thermal conductivity: a fluorescent wafer having higher thermal conductivity as compared to fluorescent powders simply doped in colloid is more effective in heat transfer; high luminous efficacy: by avoiding the optical loss caused by lens, the luminous efficacy of the white light LED device is 5˜10% higher than that of devices using common wafers; and, realizing a 360° stereo-luminescence.

The purpose, technical solutions and beneficial effects of the present invention are described with reference to the above particular examples. Nevertheless, it will be understood that the above examples are not provided to limit the present invention. The invention is intended to cover various modifications and equivalent arrangements included within the spirit and scope of the claims.

1. A white light LED filament comprising:
light emitting units arranged along a channel of a fluorescent wafer substrate such that the light emitting units are surrounded on three sides by the fluorescent wafer;
the light emitting units each having an open side not surrounded by the fluorescent wafer;
the light emitting units comprising blue-emitting chips connected by a metal wire or an electric conductive circuit; and
each of the light emitting units having an individual blue light reflecting layer formed on the open side.

2. The LED filament according to claim 1, wherein the composition of the strip-shaped fluorescent wafers is Ce:YAG, and the strip-shaped fluorescent wafers each have a length of 5 mm˜50 mm, a width of 1 mm˜4 mm, and a thickness of 0.2 mm˜1 mm.

3. The LED filament according to claim 1, further comprising electrodes arranged at a same end or at both ends of the fluorescent wafer.

4. The LED filament according to claim 1, wherein the light emitting units are fixed on the fluorescent wafer by silica gel, epoxy resin or a supporting frame.

5. The LED filament according to claim 4, wherein the silica gel or the epoxy resin is doped with red fluorescent powder.

6. The LED filament according to claim 1, wherein the light emitting units are alternately arranged blue-emitting chips and red-emitting chips.

7. The LED filament according to claim 1, wherein the fluorescent wafer is between the light emitting units and a glass sheet.

8. (canceled)

9. An LED lamp comprising the LED filament of any of claims 1-8.

10. The LED filament according to claim 1, wherein the fluorescent wafer is between the light emitting units and a red light supplementing layer.
